(19) United States
(12) Patent Application Publication
(10) Pub. No.: US 2025/0380506 A1
(43) Pub. Date: Dec. 11, 2025

(54) INTEGRATED CIRCUIT STRUCTURE WITH ALTERNATING N-TYPE AND P-TYPE TRANSISTORS

(71) Applicant: Abhishek A. Sharma, Portland, OR (US)

(72) Inventor: Abhishek A. Sharma, Portland, OR (US)

(21) Appl. No.: 18/739,405

(22) Filed: Jun. 11, 2024

(51) Int. Cl. H01L 27/092; H01L 21/8256; H01L 29/06; H01L 29/24; H01L 29/423; H01L 29/66; H01L 29/775; H01L 29/786

(52) U.S. Cl. CPC H10D 84/856; H10D 30/43; H10D 30/6735; H10D 30/6757; H10D 62/121; H10D 62/80; H10D 84/02; H10D 99/00

(57) ABSTRACT

In one example, an integrated circuit (IC) structure with alternating N-type and P-type transistors includes a first region and a second region over a substrate, where the first region and the second region are coplanar and include a first semiconductor material. The IC structure includes a third region coplanar with and between the first region and the second region, where the third region includes a second semiconductor material, where one of the first semiconductor material and the second semiconductor material is an N-type semiconductor material, and another of the first semiconductor material and the second semiconductor material is a P-type semiconductor material. The IC structure may include a first transistor over the first region, a second transistor over the second region, and a third transistor over the third region, wherein the third transistor is adjacent to the first transistor and the second transistor.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1 provides a perspective view of an example nanoribbon-based field-effect transistor (FET), according to some embodiments of the present disclosure.

FIG. 2 is a cross-sectional side view of an IC structure including alternating N-type and P-type transistors, in accordance with various embodiments.

FIG. 3 illustrates a cross-sectional side view of an example IC structure with alternating N-type and P-type transistors, according to some embodiments of the present disclosure.

FIGS. 4A and 4B illustrate top-down views of IC structures with alternating N-type and P-type transistors, according to some embodiments of the present disclosure.

FIG. 5 is a flow diagram of an example method for fabricating an IC structure including alternating N-type and P-type transistors, in accordance with some embodiments.

FIGS. 6A-6G provide cross-sectional side views at various stages in the fabrication of an example IC structure according to the method of FIG. 5, in accordance with some embodiments.

FIG. 7 is a top view of a wafer and dies that may include any of the IC devices disclosed herein, in accordance with any of the embodiments disclosed herein.

FIG. 8 is a side, cross-sectional view of an IC package that may include any of the IC devices disclosed herein, in accordance with various embodiments.

FIG. 9 is a side, cross-sectional view of an IC device assembly that may include any of the IC devices disclosed herein, in accordance with any of the embodiments disclosed herein.

FIG. 10 is a block diagram of an example electrical device that may include any of the IC devices disclosed herein, in accordance with any of the embodiments disclosed herein.

### DETAILED DESCRIPTION

Disclosed herein are integrated circuit (IC) structures including alternating N-type and P-type transistors. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

Complementary Metal-Oxide-Semiconductor (CMOS) refers to a type of integrated circuit design that uses complementary and symmetrical pairs of P-type and N-type metal-oxide-semiconductor field effect transistors (MOSFETs) for logic gates and other digital circuits. Typically, in order to form N-type transistors or P-type transistors, dopants are added to a semiconductor material to introduce either additional holes or additional electrons into the crystal lattice. For example, N-type dopants are dopants deliberately added to a semiconductor material (e.g., to source or drain (S/D) regions of an N-type transistor) to introduce additional electrons into the crystal lattice. N-type dopants are also known as “donor” impurities. On the other hand, P-type dopants are dopants deliberately added to a semiconductor material (e.g., to S/D regions of a P-type transistor) to introduce additional holes into the crystal lattice. P-type dopants are also known as “acceptor” impurities.

Dopants may be introduced to a region of semiconductor material via an implantation process. Generally, implantation techniques are performed over a relatively large area of semiconductor material (e.g., over an area having a width of at least around one thousand nanometers), resulting in a large region of semiconductor material that includes either N-type dopants (in the case of an N-type semiconductor material) or P-type dopants (in the case of a P-type semiconductor material). An integrated circuit die may have one or more regions of N-type semiconductor material and one or more regions of P-type semiconductor material. The relatively large dimensions of the regions of doped semiconductor material limit the possible placement of transistors on a die (e.g., N-type transistors are located in a region of N-type semiconductor material and P-type transistors are located in a region of P-type semiconductor material). Therefore, a transistor will generally be adjacent to other transistors having the same charge-carrier type (e.g., N-type transistors will generally be adjacent to other N-type transistors, and P-type transistors will generally be adjacent to other P-type transistors).

In contrast, in accordance with examples described herein, regions of N-type semiconductor material and P-type semiconductor material may be formed at much smaller scales than generally achievable with implantation techniques, which can enable fabricating an IC structure with alternating N-type and P-type transistors. In one example, an IC structure includes a first region and a second region over a substrate, where the first region and the second region are coplanar and include a first semiconductor material. The IC structure includes a third region coplanar with and between the first region and the second region, where the third region includes a second semiconductor material, and where one of the first semiconductor material and the second semiconductor material is an N-type semiconductor material, and another of the first semiconductor material and the second semiconductor material is a P-type semiconductor material. The IC structure may include a first transistor over the first region, a second transistor over the second region, and a third transistor over the third region, wherein the third transistor is adjacent to the first transistor and the second transistor.

IC structures as described herein, in particular IC structures including alternating N-type and P-type transistors, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details or/and that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures including alternating N-type and P-type transistors as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

Alternating N-type and P-type transistors may include transistors of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field.

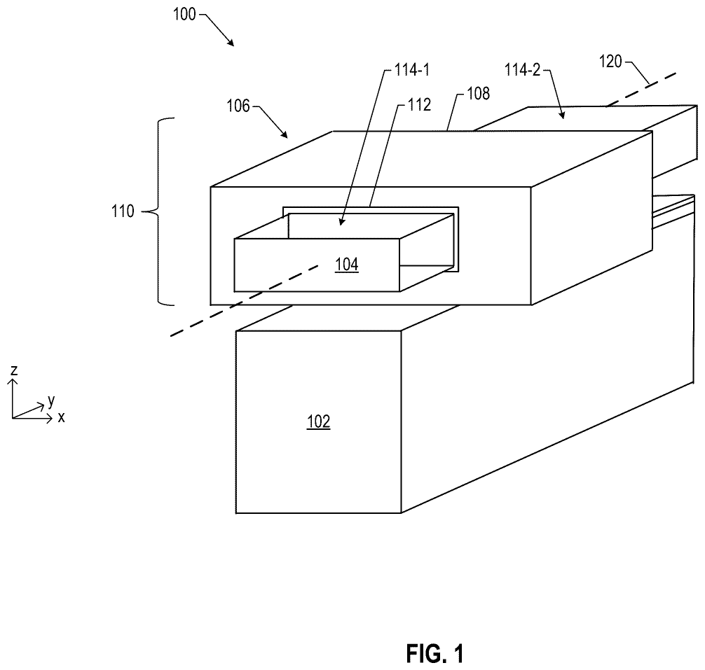

FIG. 1 provides a perspective view of an example IC structure 100 with a nanoribbon transistor 110, according to some embodiments of the present disclosure. As shown in FIG. 1, the IC structure 100 includes a semiconductor material formed as a nanoribbon 104 extending substantially parallel to a support 102. The transistor 110 may be formed on the basis of the nanoribbon 104 by having a gate stack 106 wrap around at least a portion of the nanoribbon referred to as a “channel portion” and by having source and drain regions, shown in FIG. 1 as a first S/D region 114-1 and a second S/D region 114-2 (referred to herein as simply “S/D regions” 114), on either side of the gate stack 106. One of the S/D regions 114 is a source region and the other one is a drain region. However, because, as is common in the field of FETs, designations of source and drain are often interchangeable, they are simply referred to herein as a first S/D region 114-1 and a second S/D region 114-2.

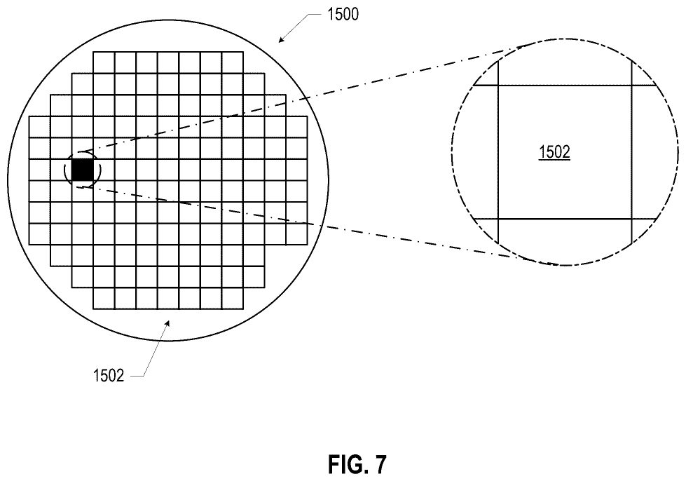

Implementations of the present disclosure may be formed or carried out on any suitable support 102, such as a substrate, a die, a wafer, or a chip. The support 102 may, e.g., be the wafer 1500 of FIG. 7, discussed below, and may be, or be included in, a die, e.g., the singulated die 1502 of FIG. 7, discussed below. The support 102 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups Il and IV of the periodic system of elements), or group IV materials (i.e., materials from group IV of the periodic system of elements). In some embodiments, the substrate may be non-crystalline. In some embodiments, the support 102 may be a printed circuit board (PCB) substrate, a package substrate, an interposer, a wafer, or a die. Although a few examples of materials from which the support 102 may be formed are described here, any material that may serve as a foundation upon which an IC structure including a self-insulated via as described herein may be built falls within the spirit and scope of the present disclosure. Although only one nanoribbon 104 is shown in FIG. 1, the IC structure 100 may include a stack of such nanoribbons where a plurality of nanoribbons 104 are stacked above one another. In some embodiments, a portion of the support 102 right below the lowest nanoribbon 104 of the stack may be shaped as a subfin extending away from a base, as is known in the field of nanoribbon transistors.

The nanoribbon 104 may take the form of a nanowire or nanoribbon, for example. In some embodiments, an area of a transversal cross-section of the nanoribbon 104 (i.e., an area in the x-z plane of an x-y-z coordinate system shown in FIG. 1, perpendicular to a longitudinal axis 120 of the nanoribbon 104) may be between about 25 and 10000 square nanometers, including all values and ranges therein (e.g., between about 25 and 1000 square nanometers, or between about 25 and 500 square nanometers). In some embodiments, a width of the nanoribbon 104 (i.e., a dimension measured in a plane parallel to the support 102 and in a direction perpendicular to the longitudinal axis 120 of the nanoribbon 104, e.g., along the x-axis of the coordinate system) may be at least about 3 times larger than a height or thickness of the nanoribbon 104 (i.e., a dimension measured in a plane perpendicular to the support 102, e.g., along the z-axis of the coordinate system), including all values and ranges therein, e.g., at least about 4 times larger, or at least about 5 times larger. Although the nanoribbon 104 illustrated in FIG. 1 is shown as having a rectangular cross-section, the nanoribbon 104 may instead have a cross-section that is rounded at corners or otherwise irregularly shaped, and the gate stack 106 may conform to the shape of the nanoribbon 104. The term “face” of a nanoribbon may refer to the side of the nanoribbon 104 that is larger than the side perpendicular to it (when measured in a plane substantially perpendicular to the longitudinal axis 120 of the nanoribbon 104), the latter side being referred to as a “sidewall” of a nanoribbon.

In various embodiments, the semiconductor material of the nanoribbon 104 may be composed of semiconductor material systems including, for example, N-type or P-type materials systems. In some embodiments, the nanoribbon 104 may include a high mobility oxide semiconductor material, such as tin oxide, antimony oxide, indium oxide, indium tin oxide, titanium oxide, zinc oxide, indium zinc oxide, gallium oxide, titanium oxynitride, ruthenium oxide, or tungsten oxide. In some embodiments, the nanoribbon 104 may include a combination of semiconductor materials. In some embodiments, the nanoribbon 104 may include a monocrystalline semiconductor, such as silicon (Si) or germanium (Ge). In some embodiments, the nanoribbon 104 may include a compound semiconductor with a first sub-lattice of at least one element from group III of the periodic table (e.g., Al, Ga, In), and a second sub-lattice of at least one element of group V of the periodic table (e.g., P, As, Sb).

For some example N-type transistor embodiments (i.e., for the embodiments where the transistor 110 is an N-type metal-oxide-semiconductor (NMOS) transistor), the channel material of the nanoribbon 104 may include a III-V material having a relatively high electron mobility, such as, but not limited to InGaAs, InP, InSb, and InAs. For some such embodiments, the channel material of the nanoribbon 104 may be a ternary III-V alloy, such as InGaAs, GaAsSb, InAsP, or InPSb. For some InₓGa₁₋ₓAs fin embodiments, In content (x) may be between 0.6 and 0.9, and may advantageously be at least 0.7 (e.g., In_{0.7}Ga_{0.3}As). For some example P-type transistor embodiments (i.e., for the embodiments where the transistor 110 is a P-type metal-oxide-semiconductor (PMOS) transistor), the channel material of the nanoribbon 104 may advantageously be a group IV material having a high hole mobility, such as, but not limited to Ge or a Ge-rich SiGe alloy. For some example embodiments, the channel material of the nanoribbon 104 may have a Ge content between 0.6 and 0.9, and advantageously may be at least 0.7.

In some embodiments, the channel material of the nanoribbon 104 may be a thin-film material, such as a high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, if the transistor formed in the nanoribbon is a thin-film transistor (TFT), the channel material of the nanoribbon 104 may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphite, and black phosphorus, each of which may possibly be doped with one or more of gallium, indium, aluminum, fluorine, boron, phosphorus, arsenic, nitrogen, tantalum, tungsten, and magnesium, etc. In some embodiments, the channel material of the nanoribbon 104 may have a thickness between about 5 and 75 nanometers, including all values and ranges therein. In some embodiments, a thin-film channel material may be deposited at relatively low temperatures, which allows depositing the channel material within the thermal budgets imposed on backend fabrication to avoid damaging other components, e.g., frontend components such as the logic devices.

A gate stack 106 including a gate electrode material 108 and, optionally, a gate insulator material 112, may wrap entirely or almost entirely around a portion of the nanoribbon 104 as shown in FIG. 1, with the active region (channel region) of the channel material of the transistor 110 corresponding to the portion of the nanoribbon 104 wrapped by the gate stack 106. As shown in FIG. 1, the gate insulator material 112 may wrap around a transversal portion of the nanoribbon 104 and the gate electrode material 108 may wrap around the gate insulator material 112.

The gate electrode material 108 may include one or more gate electrode materials, where the choice of the gate electrode materials may depend on whether the transistor 110 is a PMOS transistor or an NMOS transistor. For a PMOS transistor, gate electrode materials that may be used in different portions of the gate electrode material 108 may include, but are not limited to, ruthenium, palladium, platinum, cobalt, nickel, and conductive metal oxides (e.g., ruthenium oxide). For an NMOS transistor, gate electrode materials that may be used in different portions of the gate electrode material 108 include, but are not limited to, hafnium, zirconium, titanium, tantalum, aluminum, alloys of these metals, and carbides of these metals (e.g., hafnium carbide, zirconium carbide, titanium carbide, t mnantalum carbide, and aluminum carbide). In some embodiments, the gate electrode material 108 may include a stack of a plurality of gate electrode materials, where zero or more materials of the stack are workfunction (WF) materials and at least one material of the stack is a fill metal layer. Further materials/layers may be included next to the gate electrode material 108 for other purposes, such as to act as a diffusion barrier layer or/and an adhesion layer.

In some embodiments, the gate insulator material 112 may include one or more high-k dielectrics including any of the materials discussed herein with reference to the insulator material that may surround portions of the transistor 110. In some embodiments, an annealing process may be carried out on the gate insulator material 112 during fabrication of the transistor 110 to improve the quality of the gate insulator material 112. The gate insulator material 112 may have a thickness that may, in some embodiments, be between about 0.5 nanometers and 3 nanometers, including all values and ranges therein (e.g., between about 1 and 3 nanometers, or between about 1 and 2 nanometers). In some embodiments, the gate stack 106 may be surrounded by a gate spacer, not shown in FIG. 1. Such a gate spacer would be configured to provide separation between the gate stack 106 and S/D contacts of the transistor 110 and could be made of a low-k dielectric material, some examples of which have been provided above.

Turning to the S/D regions 114 of the transistor 110, in some embodiments, the S/D regions may be highly doped, e.g., with dopant concentrations of about 10²¹ cm⁻³, in order to advantageously form Ohmic contacts with the respective S/D contacts (not shown in FIG. 1), although these regions may also have lower dopant concentrations and may form Schottky contacts in some implementations. Irrespective of the exact doping levels, the S/D regions of a transistor are the regions having dopant concentration higher than in other regions, e.g., higher than a dopant concentration in the transistor channel (i.e., in a channel material extending between the first S/D region 114-1 and the second S/D region 114-2), and, therefore, may be referred to as “highly doped” (HD) regions. Even when doped to realize threshold voltage tuning as described herein, the channel portions of transistors typically include semiconductor materials with doping concentrations significantly smaller than those of the S/D regions 114.

The S/D regions 114 of the transistor 110 may generally be formed using either an implantation/diffusion process or an etching/deposition process. In the former process, dopants such as boron, aluminum, antimony, phosphorous, or arsenic may be ion-implanted into the nanoribbon 104 to form the source and drain regions. An annealing process that activates the dopants and causes them to diffuse further into the nanoribbon 104 may follow the ion implantation process. In the latter process, portions of the nanoribbon 104 may first be etched to form recesses at the locations of the future S/D regions 114. An epitaxial deposition process may then be carried out to fill the recesses with material that is used to fabricate the S/D regions 114. In some implementations, the S/D regions 114 may be fabricated using a silicon alloy such as silicon germanium or silicon carbide. In some implementations, the epitaxially deposited silicon alloy may be doped in situ with dopants such as boron, arsenic, or phosphorous. In further embodiments, the S/D regions 114 may be formed using one or more alternate semiconductor materials such as germanium or a group III-V material or alloy. And in further embodiments, one or more layers of metal and/or metal alloys may be used to form the S/D regions 114. In some embodiments, a distance between the first and second S/D regions 114 (i.e., a dimension measured along the longitudinal axis 120 of the nanoribbon 104) may be between about 5 and 40 nanometers, including all values and ranges therein (e.g., between about 22 and 35 nanometers, or between about 20 and 30 nanometers).

The IC structure 100 shown in FIG. 1, as well as IC structures shown in other drawings of the present disclosure, is intended to show relative arrangements of some of the components therein, and the IC structure 100, or portions thereof, may include other components that are not illustrated (e.g., electrical contacts to the S/D regions 114 of the transistor 110, additional layers such as a spacer layer around the gate electrode of the transistor 110, etc.). For example, although not specifically illustrated in FIG. 1, a dielectric spacer may be provided between a first S/D contact (which may also be referred to as a “first S/D electrode”) coupled to a first S/D region 114-1 of the transistor 110 and the gate stack 106 as well as between a second S/D contact (which may also be referred to as a “second S/D electrode”) coupled to a second S/D region 114-2 of the transistor 110 and the gate stack 106 in order to provide electrical isolation between the source, gate, and drain electrodes. In another example, although not specifically illustrated in FIG. 1, at least portions of the transistor 110 may be surrounded in an insulator material, such as any suitable interlayer dielectric (ILD) material. In some embodiments, such an insulator material may be a high-k dielectric including elements such as hafnium, silicon, oxygen, titanium, tantalum, lanthanum, aluminum, zirconium, barium, strontium, yttrium, lead, scandium, niobium, and zinc. Examples of high-k materials that may be used for this purpose may include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, tantalum oxide, tantalum silicon oxide, lead scandium tantalum oxide, and lead zinc niobate. In other embodiments, the insulator material surrounding portions of the transistor 110 may be a low-k dielectric material. Some examples of low-k dielectric materials include, but are not limited to, silicon dioxide, carbon-doped oxide, silicon nitride, organic polymers such as perfluorocyclobutane or polytetrafluoroethylene, fused silica glass (FSG), and organosilicates such as silsesquioxane, siloxane, or organosilicate glass.

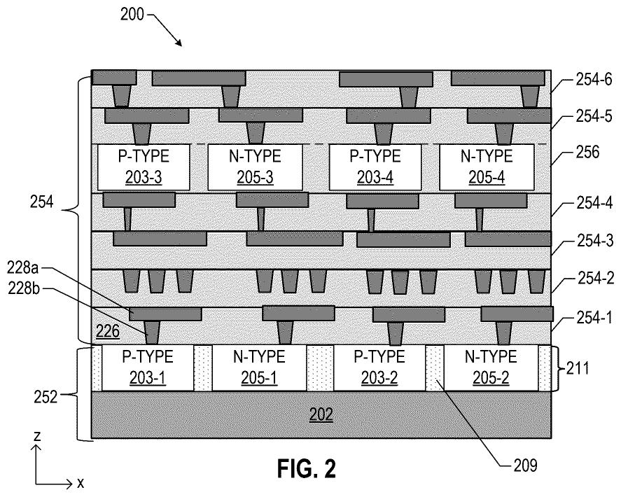

FIG. 2 is a cross-sectional side view of an IC structure including alternating N-type and P-type transistors, in accordance with various embodiments.

The IC structure 200 includes front end of line (FEOL) layers 252 and back end of line (BEOL) layers 254. FEOL and BEOL refer to two stages of semiconductor manufacturing. The first stage is referred to as the FEOL. The second stage is referred to as the BEOL. In the FEOL, individual semiconductor devices components (e.g., transistor, capacitors, resistors, etc.) can be patterned in a wafer. In the BEOL, interconnect structures such as conductive lines and conductive vias, separated as needed by an insulator material, can be formed to get the individual components interconnected. The FEOL layer 252 includes a device region 211 over a substrate 202, where the device region 211 includes devices (of which devices 203-1, 203-2, 203-3, 203-4, 205-1, 205-2, 205-3, and 205-4 are shown, where devices 203-1-203-4 may be referred to as devices 203, and devices 205-1-205-4 may be referred to as devices 205). The substrate 202 may be an example of the substrates discussed above with respect to FIG. 1.

The devices 203, 205 in the device region 211 are examples of frontend devices (e.g., frontend transistors such as FinFETs, nanowire transistors, nanoribbon transistors, frontend memory cells, or other frontend devices). The devices 203, 205 in the device region 211 may be considered “frontend devices” due to their location in a FEOL layer. According to examples, the devices 203, 205 may include transistors of any architecture, such as any non-planar or planar architecture. Devices in the device region 211 may be electrically isolated from one another by any suitable insulator material 209.

The BEOL layers 254 may include a plurality of backend interconnects electrically coupled to (e.g., in electrically conductive contact with at least portions of) one or more of the plurality of FEOL devices of the FEOL layer 252. Various BEOL interconnect layers 254 may be/include one or more metal layers of a metallization stack of the IC device. Various metal layers of the BEOL interconnect layers 254 may be used to interconnect the various inputs and outputs of the devices (e.g., logic devices) in the FEOL layer 252. In one example, each of the BEOL interconnect layers 254 may include vias and lines/trenches. For example, the BEOL interconnect layer 254-1 includes a via portion 228b and a line or trench/interconnect portion 228a. The trench portion 228a of a metal layer is configured for transferring signals and power along electrically conductive (e.g., metal) lines (also sometimes referred to as “trenches”) extending in the x-y plane (e.g., in the x or y directions), while the via portion 228b of a metal layer is configured for transferring signals and power through electrically conductive vias extending in the z-direction, e.g., to any of the adjacent metal layers above or below. Accordingly, in one example, vias connect metal structures (e.g., metal lines or vias) from one metal layer to metal structures of an adjacent metal layer. While referred to as “metal” layers, various layers of the BEOL interconnect layers 254 may include only certain patterns of conductive metals, e.g., copper (Cu), aluminum (Al), tungsten (W), or cobalt (Co), or metal alloys, or more generally, patterns of an electrically conductive material, formed in an insulating medium such as an ILD 226. The insulating medium may include any suitable ILD materials such as silicon oxide, carbon-doped silicon oxide, silicon carbide, silicon nitride, aluminum oxide, and/or silicon oxynitride. In some embodiments, the dielectric material 226 disposed between the interconnect structures in different ones of the interconnect layers may have different compositions; in other embodiments, the composition of the dielectric material 226 between different interconnect layers may be the same. The example illustrated in FIG. 2 depicts six interconnect layers 254-1-254-6, however, fewer or more interconnect layers may be present.

The IC structure 200 may also include backend devices, as shown in FIG. 2 (e.g., the devices 203, 205 in a BEOL device region 256). The devices 203, 205 in and/or over an interconnect layer may be considered “backend devices” due to their location in a BEOL layer. In the example illustrated in FIG. 2, the devices 203, 205 in the BEOL device region 256 are shown as being over four interconnect layers (e.g., layers 254-1-254-4); however, backend devices may be present in lower or higher up interconnect layers in the metallization stack. In one example, the devices 203, 205 in the BEOL device region 256 may include a transistor of any architecture, such as any non-planar or planar architecture, or other device.

As mentioned briefly above, typically, in order to form N-type transistors or P-type transistors, a large area of semiconductor material is implanted with impurities to form a region of semiconductor material having the desired charge-carrier type. For example, a large region may be implanted with P-type dopants for fabricating P-type transistors, and another large region may be implanted with N-type dopants for fabricating N-type transistors.

In an N-type FET, the source and drain regions are doped with N-type dopants (with dopant concentrations of at least 10¹⁷ dopants per cubic cm, or more, e.g., with dopant concentrations of at least 10¹⁸ dopants per cubic cm or with dopant concentrations of at least 10²⁰ dopants per cubic cm) to create regions with an excess of electrons that can serve as the majority charge carriers during operation of the N-type FET, while the channel region may be lightly doped (also with N-type dopants, e.g., a lightly doped channel region may have dopant concentrations between about 10¹⁴ dopants per cubic cm and about 10¹⁷, or 0.5×10¹⁷, dopants per cubic cm) or undoped/intrinsic (e.g., the channel region may have dopant concentrations below about 10¹³ dopants per cubic cm, e.g., below 10¹² dopants per cubic cm).

In a P-type FET, the source and drain regions are doped with P-type dopants (with dopant concentrations of at least 10¹⁷ dopants per cubic cm, or more, e.g., with dopant concentrations of at least 10¹⁸ dopants per cubic cm or with dopant concentrations of at least 10²⁰ dopants per cubic cm) to create regions with an excess of holes (or deficiencies of electrons) that can serve as the majority charge carriers during operation of the P-type FET, while the channel region may be lightly doped (also with P-type dopants, e.g., a lightly doped channel region may have dopant concentrations between about 10¹⁴ dopants per cubic cm and about 10¹⁷, or 0.5×10¹⁷, dopants per cubic cm) or undoped/intrinsic (e.g., the channel region may have dopant concentrations below about 10¹³ dopants per cubic cm, e.g., below 10¹² dopants per cubic cm).

Generally, the width of the implanted area is at least around one thousand nanometers, and may be larger depending on the implementation (where the width of the implanted area refers to a dimension of the implanted area in a plane substantially parallel to the substrate, or along the x-y plane as shown in FIG. 2, where the y-axis is going into and coming out of the page). Therefore, a given region will generally have only either N-type transistors or P-type transistors, but not both N- type and P-type transistors.

In contrast, the IC structure 200 may include alternating N-type and P-type transistors (e.g., the devices 203, 205) in the FEOL layers 252 and/or in the BEOL layers 254. Unlike conventional IC structures in which N-type transistors are generally surrounded by only other N-type transistors and P-type transistors are generally surrounded by only other P-type transistors, the IC structure 200 may include a first transistor of one charge carrier type (e.g., either N-type or P-type) that has second transistors of the other charge carrier type on multiple sides of the first transistor (e.g., on either side of the first transistor, bordering three sides of the first transistor, bordering four sides of the first transistor, etc.). For example, an IC structure may include a first transistor (e.g., the transistor 205-1) and a second transistor (e.g., the transistor 205-2) in a plane that is substantially parallel to a substrate (e.g., in the x-y plane shown in FIG. 2). The first transistor includes a first semiconductor portion with dopants of a first charge carrier type (e.g., N-type), where the first semiconductor portion is either a first source region or a first drain region of the first transistor. The second transistor includes a second semiconductor portion with dopants of the first charge carrier type (e.g., N-type), where the second semiconductor portion is either a second source region or a second drain region of the second transistor. The IC structure includes a third transistor (e.g., the transistor 203-2) between the first transistor and the second transistor in the plane, where the third transistor includes a third semiconductor portion with dopants of a second charge carrier type (e.g., P-type), and where the third semiconductor portion is either a third source region or a third drain region of the third transistor.

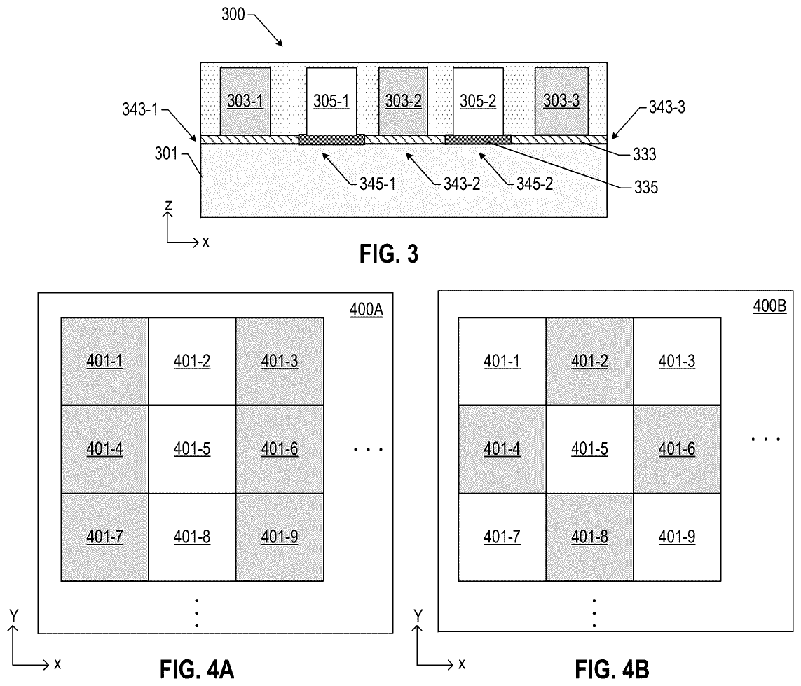

FIG. 3 illustrates a cross-sectional side view of an example IC structure 300 with alternating N-type and P-type transistors. As can be seen in FIG. 3, the IC structure 300 includes alternating transistors 303 and 305 (labeled transistors 303-1, 305-1, 303-2, 305-2, and 303-3 in FIG. 3) over a substrate 301, where one of the transistors 303, 305 are N-type transistors and the other are P-type transistors. The transistors are formed over alternating regions of N-type semiconductor material and P-type semiconductor material. For example, the IC structure 300 includes a layer between the substrate 301 and the transistor 303, 305, where the layer includes alternating regions 343, 345 of a first semiconductor material 333 and a second semiconductor material 335. For example, the IC structure includes a first region (e.g., region 343-1) including a first semiconductor material 333 below a first transistor (e.g., the transistor 303-1), a second region (e.g., the region 343-2) of the first semiconductor material 333 below a second transistor (e.g., the transistor 303-2), and a third region (e.g., the region 345-1) of a second semiconductor material 335 below a third transistor (e.g., the transistor 305-1). In the example illustrated in FIG. 3, the second semiconductor material 335 of the third region 345-1 is between, coplanar with, and in contact with the first semiconductor material 333 of the first region 343-1 and the second region 343-2.

The regions 343, 345 may include semiconductor materials in accordance with examples described above, and the regions 343 may include a semiconductor material 333 that has a different material composition from the semiconductor material 335 of the regions 345. According to examples, one or both of the semiconductor materials 333, 335 may have been converted into a semiconductor material from a conductive material including a metal. In one such example, as a result of its conversion from a metal, a semiconductor material that was converted may have some properties that differ from a semiconductor material that is deposited (e.g., with a chemical vapor deposition (CVD) process, epitaxially grown, etc.). For example, a semiconductor material that was converted from a conductive material may have a more uniform crystalline structure throughout its thickness than a deposited semiconductor material (e.g., where the thickness is a dimension of the semiconductor material in a plane substantially orthogonal to the substrate, such as along the z-axis as illustrated in FIG. 3). For example, a deposited semiconductor material may start with small grains on the surface upon which the semiconductor material is deposited and grow from the small grains, which may result in a gradient (e.g., from smaller to larger) of grain sizes along the thickness of the semiconductor material. In contrast, a semiconductor material converted from a conductive material may have a substantially uniform grain size along a thickness of the semiconductor material due to starting with a relatively uniform metal layer that is then converted (e.g., via exposure to a gas and elevated temperatures). Also as a result of conversion from a conductive material, there may be no grain boundaries in at least about the first 2 nanometers of the semiconductor material (e.g., from an interface with another material) in the z-direction. For example, if the thickness of a semiconductor material that was converted is the dimension of the semiconductor material between a first material below the semiconductor material and a second material over the semiconductor material, a grain boundary may be absent from the semiconductor material in at least a first 2 nanometers of the thickness from a first interface with the first material towards a second interface with the second material. In one such example, such semiconductor materials converted from a conductive material may utilize a two-dimensional (2D) electron gas to facilitate charge carrier transport.

One example of semiconductor materials that may be formed by converting a conductive material are oxide semiconductors. For example, indium oxide may be formed by first depositing a layer of indium and converting the indium to indium oxide (e.g., via exposure to oxygen at elevated temperatures). Another example of semiconductor materials that are converted from a conductive material are semiconductive transition metal dichalcogenides (TMDs). TMDs include semiconducting materials formed form a combination of a transition metal (e.g., molybdenum or tungsten) and a chalcogen (e.g., sulfur or selenium) in a monolayer having a hexagonal crystal structure. TMDs are atomically thin materials having the general formula MX₂, where M is a transition metal such as molybdenum (Mo), tungsten (W), or zirconium (Zr), and X is a chalcogen atom (sulfur (S), selenium (Se), or tellurium (Te)). TMDs that include Mo, W, or Zr as the transition metal are semiconducting. For example, MoS₂ and WS₂ are examples of N-type semiconductor materials, and MoSe₂ is an example of a P-type semiconductor material. TMD materials are in the class of 2D materials, also referred to as single-layer materials, such as graphene. 2D materials are crystalline materials that may be formed from a single material layer, e.g., a single layer of atoms. In some examples, a 2D material may include multiple monolayers and still be referred to as a 2D material. A single layer of a TMD, also referred to as a monolayer TMD, is composed of three atomic planes: two planes of the chalcogen atoms and one plane of the transition metal atoms. The transition metal (M) atoms are sandwiched between the two layers of the chalcogen (X) atoms.

Thus, as mentioned above, the semiconductor material 333 may be a different material from the semiconductor material 335. In some examples, the regions 343, 345 may include a TMD and another type of semiconductor material (such as an oxide semiconductor), different TMDs, different oxide semiconductors, or an oxide semiconductor and another type of semiconductor. In one such example, one of the first and second semiconductor materials 333, 335 is a TMD and another of the first and second semiconductor materials 333, 335 is a semiconductor including oxygen. In another example, one of the first and second semiconductor materials 333, 335 is a first TMD and another of the first and second semiconductor materials 333, 335 is a second TMD. In another example, one of the first and second semiconductor materials 333, 335 is a first semiconductor including oxygen and another of the first and second semiconductor materials 333, 335 is a second semiconductor including oxygen. One or more of the semiconductor materials 333, 335 may also, or alternatively, be a 2D material.

The widths of the regions 343, 345 may vary depending on implementation, but in some examples, the widths of the alternating regions 343, 345 may be significantly smaller than the width of conventional regions of P-type semiconductor material or N-type semiconductor material. In one example where the transistors 303, 305 are non-planar transistors that include a fin or nanoribbon stack, the width of the regions 343, 345 over which the transistors 303, 305 are formed may be as small as about the width of the fin or nanoribbon stack. For example, the transistor 303-1 may include a fin or nanoribbon stack with a first width, where the first width is a dimension of the fin or nanoribbon stack in the x-y plane (e.g., along the x-axis), the region 343-1 has a second width, where the second width is a dimension of the region 343-1 in the x-y plane, and the second width may be in a range of about 1-2 times the first width. In other examples, the region may have other dimensions (e.g., may be larger than 2 times the width of the transistor fin or nanoribbon stack).

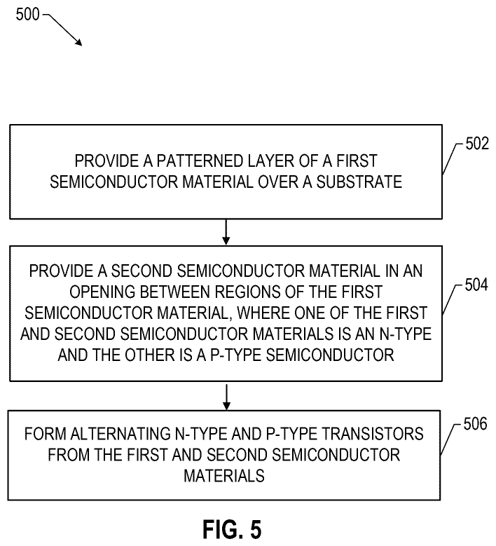

An IC structure including alternating N-type and P-type transistors may include a variety of patterns of alternating N-type semiconductor regions and P-type semiconductor regions. FIGS. 4A and 4B illustrate top-down views of IC structures 400A, 400B with alternating N-type and P-type transistors. Specifically, each of the IC structures 400A and 400B illustrate a plurality of coplanar devices 401-1-401-9 (where the devices 401-1-401-9 may be referred to generally as devices 401). The devices 401 are shown as having a top-down square shape in FIGS. 4A and 4B; however, the devices 401 may include devices, such as transistors, of any architecture and thus may have a variety of shapes. In FIGS. 4A and 4B, a given box (e.g., the box labeled device(s) 401-1) may represent a single transistor, or multiple transistors (e.g., two transistors, three transistors, four transistors, or more than four transistors). In FIGS. 4A and 4B, some of the boxes indicating the location of devices 401 are unshaded (e.g., white), while other boxes indicating the location of devices 401 are shaded grey. For example, in FIG. 4A, the boxes indicating devices 401-1, 401-3, 401-4, 401-6, 401-7, and 401-9 are shaded grey, while the boxes indicating the devices 401-2, 401-5, and 401-8 are white. In FIGS. 4A and 4B, the boxes indicating the devices 401 that are shaded grey indicate devices of one charge-carrier type, and the boxes indicating devices 401 that are white indicate devices of another charge-carrier type, where the charge carrier type is either N-type or P-type. For example, the white boxes may indicate N-type devices and the grey boxes may indicate P-type devices, or vice versa.

Referring to FIG. 4A, the IC structure 400A includes strips of alternating N-type and P-type devices (e.g., where a strip has a larger length than width) that are over and aligned with strips of alternating N-type semiconductor material and P-type semiconductor material. For example, as shown in FIG. 4A, the devices 401-1, 401-4, and 401-7 may be over a first strip of a first semiconductor material (e.g., having a length along the y-axis as shown in FIG. 4A), the devices 401-3, 401-6, and 401-9 may be over a second strip of the first semiconductor material, and the devices 401-2, 401-5, and 401-8 may be over a third strip of a second semiconductor material. In the example illustrated in FIG. 4A, the alternate strips of semiconductor material are adjacent to one another, parallel, and coplanar. Thus, FIG. 4A illustrates an example in which the regions of semiconductor material are alternating along a single axis (e.g., along the x-axis as shown in FIG. 4A).

FIG. 4B illustrates another IC structure 400B in which the N-type and P-type transistors are alternating along two axes (e.g., in along both the x-axis and the y-axis as shown in FIG. 4B). For example, the IC structure 400B includes a first transistor (e.g., the device 401-4), a second transistor (e.g., the device 401-6), and a third transistor (e.g., the device 401-5) along a first axis in a plane substantially parallel with the substrate (e.g., along the x-axis). The IC structure 400B also includes a fourth transistor (e.g., the device 401-2) adjacent to the third transistor along a second axis that is substantially orthogonal to the first axis (e.g., along the y-axis). In this example, the first transistor, second transistor, and fourth transistor include S/D regions with dopants of a first charge carrier type, and the third transistor includes an S/D region with dopants of a second charge carrier type (e.g., where one of the first charge carrier type and the second charge carrier type is an N-type and another one of the first charge carrier type and the second charge carrier type is a P-type). Thus, as can be seen in this example, the IC structure 400B may include alternating transistor along two different (e.g., two orthogonal) axes in the plane.

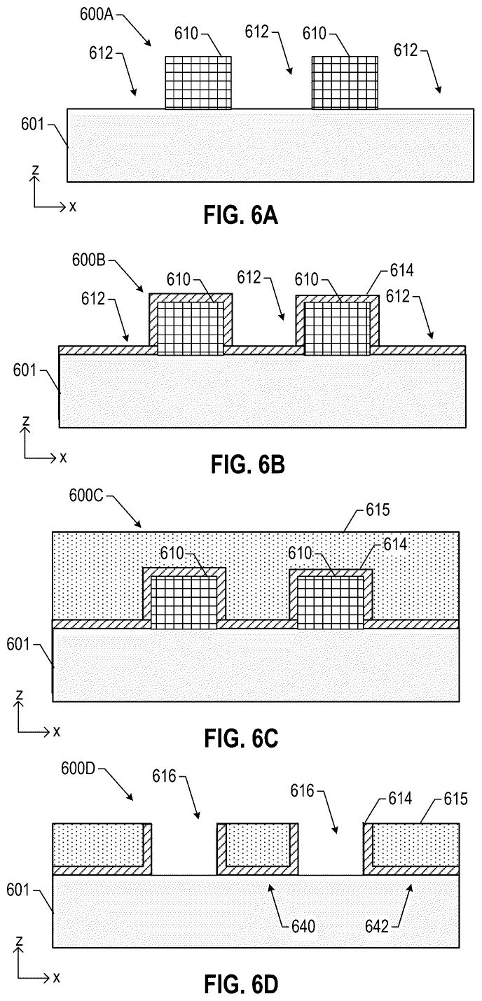

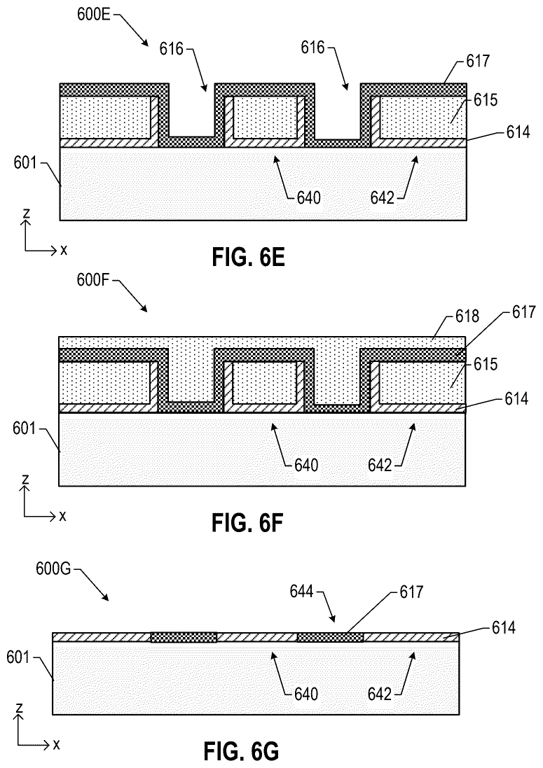

FIG. 5 is a flow diagram of an example method 500 for fabricating an IC structure including alternating N-type and P-type transistors. FIGS. 6A-6G provide cross-sectional side views at various stages in the fabrication of an example IC structure according to the method of FIG. 5, in accordance with some embodiments. Although the operations of the method of FIG. 5 are illustrated once each and in a particular order, the operations may be performed in any suitable order and repeated as desired. For example, one or more operations may be performed in parallel to fabricate multiple IC structures including alternating N-type and P-type transistors substantially simultaneously. In another example, the operations may be performed in a different order to reflect the structure of an IC device in which alternating N-type and P-type transistors will be implemented.

In addition, the example fabricating methods of FIG. 5 may include other operations not specifically shown in FIG. 5, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., a chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIG. 5 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 5, the method 500 begins with a process 502 of providing a patterned layer of a first semiconductor material over a substrate, where the patterned layer includes: a first region of the first semiconductor material, a second region of the first semiconductor material, and an opening between the first region and the second region. In one example, providing the patterned layer of the first semiconductor material may first involve providing a mask with first openings over a substrate. The IC structure 600A of FIG. 6A is an example resulting structure of providing a mask with first openings over a substrate. The IC structure 600A includes a mask 610 with openings 612 over a substrate 601. The substrate may be an example of the substrates described above. In an example in which backend devices are being formed, the substrate 601 may include a BEOL layer (e.g., an interconnect layer). The mask may be formed according to any suitable patterning technique.

The method 500 may then involve providing a first semiconductor material in the openings. The IC structure 600B of FIG. 6B is an example resulting structure of providing a first semiconductor material in the openings. As can be seen in FIG. 6B, a layer of semiconductor material 614 is provided in the openings 612 (e.g., at the bottom of the openings). In the example in FIG. 6B, the semiconductor material 614 is also provided over the mask and on sidewalls of the openings. Providing the layer of semiconductor material 614 may involve any suitable deposition technique, such as atomic layer deposition (ALD), CVD, physical vapor deposition (PVD), epitaxial deposition, conversion from a conductive material using a gas treatment, or any other technique may be used. In one example, providing a layer of semiconductor material by converting a layer of conductive material may involve first depositing a layer of conductive material (e.g., using an ALD process or other suitable deposition technique). A treatment, such as a gas treatment, may then be performed on the conductive material. In one example, a gas treatment involves exposing the conductive material to a gas (e.g., hydrogen sulfide, hydrogen selenide, oxygen, or other gas) at a temperature in a range of about 350 to 600 degrees C.

The method 500 may continue with filling the openings with an insulator material over the first semiconductor material. The IC structure 600C of FIG. 6C is an example resulting structure of filling the openings with an insulator material. As can be seen in FIG. 6C, the IC structure includes an insulator material 615 in the openings 612. The insulator material 615 may be any suitable insulator material, such as those discussed above. The method may then involve recessing the insulator material to expose the first semiconductor material over the mask, etching the exposed first semiconductor material over the mask, and removing the mask. The IC structure 600D of FIG. 6D is an example resulting structure of recessing the insulator material to expose the first semiconductor material over the mask, etching the exposed first semiconductor material over the mask, and removing the mask. As can be seen in FIG. 6D, removal of the mask 610 results in openings 616 between adjacent regions of the first semiconductor material 614. Thus, FIGS. 6A-6B illustrate one technique for providing a patterned layer of a first semiconductor material 614 over a substrate 601, where the patterned layer includes: a first region 640 of the first semiconductor material 614, a second region 642 of the first semiconductor material 614, and an opening 616 between the first region 640 and the second region 642. Other techniques may also be used to provide a patterned layer of a first semiconductor material 614.

Referring again to FIG. 5, the method continues with the process 504 of providing a second semiconductor material in the opening, wherein one of the first semiconductor material and the second semiconductor material includes an N-type semiconductor material and another of the first semiconductor material and the second semiconductor material includes a P-type semiconductor material. The IC structure 600E of FIG. 6E is an example resulting structure of the process 504. As can be seen in FIG. 6E, the IC structure 600E includes a layer of a second semiconductor material 617 in the openings 616. In the example illustrated in FIG. 6E, the second semiconductor material 617 is also present over a top of the insulator material 615 and on sidewalls of the openings 616. The method may then involve filling the openings 616 with an insulator material. The IC structure 600F of FIG. 6F is an example resulting structure of filling the openings 616 with an insulator material 618. The insulator material 618 may be any suitable insulator material, such as those discussed above, and may be substantially the same or different from the insulator material 615. The method may then involve etching various materials of the IC structure according to any suitable etching and/or polishing techniques to expose the second semiconductor material 617 at the bottom of the openings 616 and to expose the first semiconductor material 614, such as shown in the IC structure 600G of FIG. 6G.

The method 500 may then involve the process 506 of forming a first transistor over the first semiconductor material of the first region, a second transistor over the first semiconductor material of the second region, and a third transistor over the second semiconductor material and adjacent to the first and second transistors. The transistors may be formed in accordance with known techniques over the alternating regions of N-type semiconductor material and P-type semiconductor material.

Thus, FIG. 5 illustrates a method 500 for fabricating an IC structure including alternating N-type and P-type transistors. Performing the method 500 may result in several features in the final IC structures that are characteristic of the use of the method 500. For example, one such feature is illustrated in an IC structure 600G shown in FIG. 6G, in which a first region 640 and a second region 642 are coplanar and include a first semiconductor material 614, a third region 644 is coplanar with and between the first region 640 and the second region 642, where the third region 644 includes a second semiconductor material 617. One of the first semiconductor material 614 and the second semiconductor material 617 is an N-type semiconductor material, and another of the first semiconductor material 614 and the second semiconductor material 617 is a P-type semiconductor material.

IC devices/structures including alternating N-type and P-type transistors as described herein (e.g., as described with reference to FIGS. 2, 3, 4A-4B, 5, and 6A-6G) may be used to implement any suitable components. For example, in various embodiments, IC devices described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), etc.

The IC devices/structures disclosed herein, e.g., the IC structures 200, 300, 400A, 400B, or any variations thereof, may be included in any suitable electronic component. FIGS. 7-10 illustrate various examples of apparatuses that may include any of the IC devices disclosed herein.

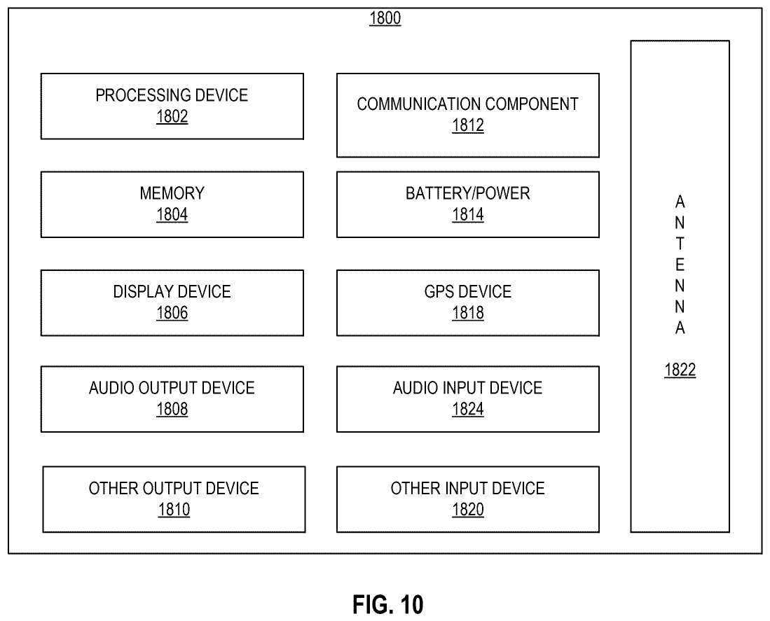

FIG. 7 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures as described herein (e.g., any of the IC structures 200, 300, 400A, 400B, or any variations thereof described herein, or any combination of such IC structures), one or more transistors and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 10) or other logic that is configured to store information in the memory devices or execute instructions stored in the memory array.

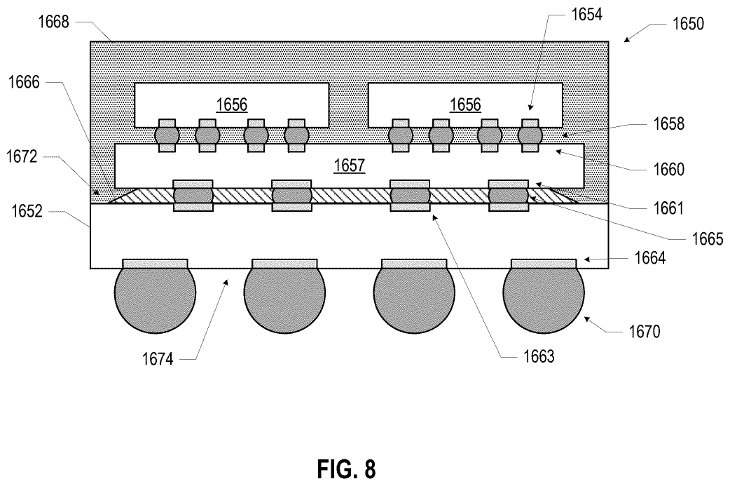

FIG. 8 is a side, cross-sectional view of an example IC package 1650 that may include one or more IC structures in accordance with any of the embodiments disclosed herein (e.g., any of the IC structures 200, 300, 400A, 400B, or any variations thereof described herein, or any combination of such IC structures). In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 8 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 8 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

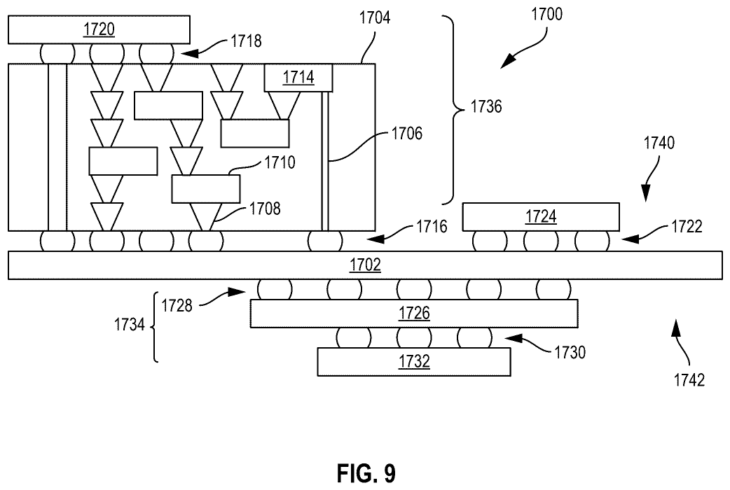

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 8 are solder balls (e.g., for a ball grid array arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 9.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 8 is a flip chip package, other package architectures may be used. For example, the IC package 1650 may be a ball grid array (BGA) package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 8, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

FIG. 9 is a side, cross-sectional view of an IC device assembly 1700 that may include one or more IC packages or other electronic components (e.g., a die) including one or more IC devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 8 (e.g., may include one or more of the IC structures 200, 300, 400A, 400B, or any variations thereof described herein, or any combination of such IC structures).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 9 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 9), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 9, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 7), an IC device (e.g., any of the IC structures 200, 300, 400A, 400B, or any variations thereof described herein, or any combination of such IC structures), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 9, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on- interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 9 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 10 is a block diagram of an example electrical device 1800 that may include one or more IC structures 100 in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 10 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 10, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded dynamic random-access memory (eDRAM) or spin transfer torque magnetic random-access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include an other output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include an other input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure, including a first transistor and a second transistor in a plane substantially parallel to a substrate over which the first and second transistors are disposed, where: the first transistor includes a first semiconductor portion with dopants of a first charge carrier type, where the first semiconductor portion is either a first source region or a first drain region of the first transistor, and the second transistor includes a second semiconductor portion with dopants of the first charge carrier type, where the second semiconductor portion is either a second source region or a second drain region of the second transistor; and a third transistor between the first transistor and the second transistor in the plane, where: the third transistor includes a third semiconductor portion with dopants of a second charge carrier type, where the third semiconductor portion is either a third source region or a third drain region of the third transistor, and one of the first charge carrier type and the second charge carrier type is an N-type and another one of the first charge carrier type and the second charge carrier type is a P-type.

Example 2 provides the IC structure of example 1, further including a layer between the substrate and the first transistor, where the layer includes a first region including a first semiconductor material below the first transistor, a second region of the first semiconductor material below the second transistor, and a third region of a second semiconductor material below the third transistor, where the second semiconductor material of the third region is between, coplanar with, and in contact with the first semiconductor material of the first region and the second region.

Example 3 provides the IC structure of example 2, where: the first transistor is a nonplanar transistor including a fin or nanoribbon stack; the fin or nanoribbon stack has a first width; the first width is a dimension of the fin or nanoribbon stack in the plane; the first region has a second width; the second width is a dimension of the first region in the plane; and the second width is in a range of about 1-2 times the first width.

Example 4 provides the IC structure of examples 2 or 3, where: the first semiconductor material has a different material composition from the second semiconductor material.

Example 5 provides the IC structure of any one of examples 2-4, where: the plane is a first plane; and at least one of the first semiconductor material and the second semiconductor material includes a semiconductor material (e.g., semiconductor material converted from a conductive material) that has substantially uniform grain size along a thickness of the semiconductor material, where the thickness is a dimension of the semiconductor material in a second plane substantially orthogonal to the substrate.

Example 6 provides the IC structure of any one of examples 2-5, where: one of the first and second semiconductor materials is a transition metal dichalcogenide and another of the first and second semiconductor materials is a semiconductor including oxygen.

Example 7 provides the IC structure of any one of examples 2-5, where: one of the first and second semiconductor materials is a first TMD and another of the first and second semiconductor materials is a second TMD.

Example 8 provides the IC structure of any one of examples 2-5, where: one of the first and second semiconductor materials is a first semiconductor including oxygen and another of the first and second semiconductor materials is a second semiconductor including oxygen.

Example 9 provides the IC structure of any one of examples 2-8, where: the first region, the second region, and the third region include alternate strips of the first semiconductor material and the second semiconductor material (e.g., where the alternate strips are adjacent to one another, parallel, and coplanar), including: a first strip of the first semiconductor material (e.g., having a first length and a first width, where first length and the first width are orthogonal dimensions of the first strip in the plane, where the first length is greater than the first width), a second strip of the first semiconductor material (e.g., having a second length and a second width, where second length and the second width are orthogonal dimensions of the second strip in the plane, and where the second length is greater than the second width), and a third strip of the second semiconductor material between and in contact with the first strip and the second strip (e.g., where the third strip has a third length and a third width, where third length and the third width are orthogonal dimensions of the third strip in the plane, and where the third length is greater than the third width).

Example 10 provides the IC structure of any one of examples 1-9, where: the first transistor, the second transistor, and the third transistor are along a first axis in the plane; the IC structure further includes a fourth transistor adjacent to the third transistor along a second axis that is substantially orthogonal to the first axis; and the fourth transistor includes a fourth semiconductor portion with dopants of the first charge carrier type, where the fourth semiconductor portion is either a fourth source region or a fourth drain region of the fourth transistor.

Example 11 provides the IC structure of any one of examples 1-10, where: the first transistor, the second transistor, and the third transistor are in front end of line layers.

Example 12 provides the IC structure of any one of examples 1-10, where: the first transistor, the second transistor, and the third transistor are in back end of line layers.

Example 13 provides an IC structure, including a substrate; a first region and a second region over the substrate, where the first region and the second region are coplanar and include a first semiconductor material; a third region coplanar with and between the first region and the second region, where: the third region includes a second semiconductor material, one of the first semiconductor material and the second semiconductor material is an N-type semiconductor material, and another of the first semiconductor material and the second semiconductor material is a P-type semiconductor material; and a first transistor over the first region, a second transistor over the second region, and a third transistor over the third region, where the third transistor is adjacent to the first transistor and the second transistor.

Example 14 provides the IC structure of example 13, where: intervening transistors are absent from between the first transistor and the third transistor, and absent from between the second transistor and the third transistor.

Example 15 provides the IC structure of examples 13 or 14, where: the first transistor has a first width, where the first width is a dimension of the first transistor in a plane substantially parallel with the substrate; the first region has a second width, where the second width is a dimension of the first region in the plane; and the second width is in a range of about 1-2 times the first width.

Example 16 provides the IC structure of any one of examples 13-15, where: the first semiconductor material has a different material composition from the second semiconductor material.

Example 17 provides the IC structure of any one of examples 13-16, where: the first semiconductor material includes a TMD or a semiconductor material including oxygen.

Example 18 provides the IC structure of any one of examples 13-17, where: the second semiconductor material includes a TMD or a semiconductor material including oxygen.

Example 19 provides an IC structure according to any one of examples 1-18, where the IC structure includes or is a part of a central processing unit.

Example 20 provides an IC structure according to any one of examples 1-19, where the IC structure includes or is a part of a memory device.

Example 21 provides an IC structure according to any one of examples 1-20, where the IC structure includes or is a part of a logic circuit.

Example 22 provides an IC structure according to any one of examples 1-21, where the IC structure includes or is a part of input/output circuitry.

Example 23 provides an IC structure according to any one of examples 1-22, where the IC structure includes or is a part of a field programmable gate array transceiver.

Example 24 provides an IC structure according to any one of examples 1-23, where the IC structure includes or is a part of a field programmable gate array logic.

Example 25 provides an IC structure according to any one of examples 1-24, where the IC structure includes or is a part of a power delivery circuitry.

Example 26 provides an IC package that includes an IC die including an IC structure according to any one of examples 1-25; and a further IC component, coupled to the IC die.

Example 27 provides an IC package according to example 26 where the further IC component includes a package substrate.

Example 28 provides an IC package according to example 26, where the further IC component includes an interposer.

Example 29 provides an IC package according to example 26, where the further IC component includes a further IC die.

Example 30 provides a computing device that includes a carrier substrate and an IC structure coupled to the carrier substrate, where the IC structure is an IC structure according to any one of examples 1-25, or the IC structure is included in the IC package according to any one of examples 26-29.

Example 31 provides a computing device according to example 30, where the computing device is a wearable or handheld computing device.

Example 32 provides a computing device according to examples 30 or 31, where the computing device further includes one or more communication chips.

Example 33 provides a computing device according to any one of examples 30-32, where the computing device further includes an antenna.

Example 34 provides a computing device according to any one of examples 30-33, where the carrier substrate is a motherboard.

Example 35 provides a method of fabricating an IC structure, the method including providing a patterned layer of a first semiconductor material over a substrate, where the patterned layer includes a first region of the first semiconductor material, a second region of the first semiconductor material, and an opening between the first region and the second region; providing a second semiconductor material in the opening, where one of the first semiconductor material and the second semiconductor material includes an N-type semiconductor material and another of the first semiconductor material and the second semiconductor material includes a P-type semiconductor material; and forming a first transistor over the first semiconductor material of the first region, a second transistor over the first semiconductor material of the second region, and a third transistor over the second semiconductor material and adjacent to the first and second transistors.

Example 36 provides the method of example 35, where: providing the patterned layer of the first semiconductor material includes providing a mask with first openings over the substrate, providing a first semiconductor material in the first openings, filling the first openings with an insulator material over the first semiconductor material, recessing the insulator material to expose the first semiconductor material over the mask, etching the exposed first semiconductor material over the mask, and removing the mask, where removal of the mask forms the opening.

Example 37 provides the method of examples 19 or 20, where: providing the first semiconductor material or providing the second semiconductor material includes depositing a layer of conductive material including a metal, and converting the conductive material to a semiconductor material.

Example 38 provides a method according to any one of examples 35-37, where the IC structure is an IC structure according to any one of the preceding examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a first transistor and a second transistor in a plane substantially parallel to a substrate over which the first and second transistors are disposed, wherein:
the first transistor includes a first semiconductor portion with dopants of a first charge carrier type, wherein the first semiconductor portion is either a first source region or a first drain region of the first transistor, and
the second transistor includes a second semiconductor portion with dopants of the first charge carrier type, wherein the second semiconductor portion is either a second source region or a second drain region of the second transistor; and
a third transistor between the first transistor and the second transistor in the plane, wherein:
the third transistor includes a third semiconductor portion with dopants of a second charge carrier type, wherein the third semiconductor portion is either a third source region or a third drain region of the third transistor, and
one of the first charge carrier type and the second charge carrier type is an N-type and another one of the first charge carrier type and the second charge carrier type is a P-type.

2. The IC structure of claim 1, further comprising:
a layer between the substrate and the first transistor, wherein the layer includes:
a first region including a first semiconductor material below and aligned with the first transistor,
a second region of the first semiconductor material below and aligned with the second transistor, and
a third region of a second semiconductor material below the third transistor, wherein the second semiconductor material of the third region is between, coplanar with, and in contact with the first semiconductor material of the first region and the second region.

3. The IC structure of claim 2, wherein:
the first transistor is a non-planar transistor including a fin or nanoribbon stack,
the fin or nanoribbon stack has a first width,
the first width is a dimension of the fin or nanoribbon stack in the plane,
the first region has a second width,
the second width is a dimension of the first region in the plane, and
the second width is in a range of about 1-2 times the first width.

4. The IC structure of claim 2, wherein:
the first semiconductor material has a different material composition from the second semiconductor material.

5. The IC structure of claim 2, wherein:
the plane is a first plane, and
at least one of the first semiconductor material and the second semiconductor material includes a semiconductor material that has substantially uniform grain size along a thickness of the semiconductor material, wherein the thickness is a dimension of the semiconductor material in a second plane substantially orthogonal to the substrate.

6. The IC structure of claim 2, wherein:
one of the first and second semiconductor materials is a transition metal dichalcogenide and another of the first and second semiconductor materials is a semiconductor including oxygen.

7. The IC structure of claim 2, wherein:
one of the first and second semiconductor materials is a first transition metal dichalcogenide (TMD) and another of the first and second semiconductor materials is a second TMD.

8. The IC structure of claim 2, wherein:
one of the first and second semiconductor materials is a first semiconductor including oxygen and another of the first and second semiconductor materials is a second semiconductor including oxygen.

9. The IC structure of claim 2, wherein:
the first region, the second region, and the third region include alternate strips of the first semiconductor material and the second semiconductor material, including:
a first strip of the first semiconductor material,
a second strip of the first semiconductor material, and
a third strip of the second semiconductor material between and in contact with the first strip and the second strip.

10. The IC structure of claim 1, wherein:
the first transistor, the second transistor, and the third transistor are along a first axis in the plane,
the IC structure further comprises a fourth transistor adjacent to the third transistor along a second axis that is substantially orthogonal to the first axis, and
the fourth transistor includes a fourth semiconductor portion with dopants of the first charge carrier type, wherein the fourth semiconductor portion is either a fourth source region or a fourth drain region of the fourth transistor.

11. The IC structure of claim 1, wherein:
the first transistor, the second transistor, and the third transistor are in front end of line layers.

12. The IC structure of claim 1, wherein:
the first transistor, the second transistor, and the third transistor are in back end of line layers.

13. An integrated circuit (IC) structure, comprising:
a substrate;
a first region and a second region over the substrate, wherein the first region and the second region are coplanar and include a first semiconductor material;
a third region coplanar with and between the first region and the second region, wherein:
the third region includes a second semiconductor material,
one of the first semiconductor material and the second semiconductor material is an N-type semiconductor material, and
another of the first semiconductor material and the second semiconductor material is a P-type semiconductor material; and
a first transistor having a first channel portion in the first region, a second transistor having a second channel portion in the second region, and a third transistor having a third channel portion in the third region, wherein the third transistor is adjacent to the first transistor and the second transistor.

14. The IC structure of claim 13, wherein:
intervening transistors are absent from between the first transistor and the third transistor, and absent from between the second transistor and the third transistor.

15. The IC structure of claim 13, wherein:
the first transistor has a first width, wherein the first width is a dimension of the first transistor in a plane substantially parallel with the substrate,
the first region has a second width, wherein the second width is a dimension of the first region in the plane, and
the second width is in a range of about 1-2 times the first width.

16. The IC structure of claim 13, wherein:
the first semiconductor material has a different material composition from the second semiconductor material.

17. The IC structure of claim 13, wherein:
the first semiconductor material includes a transition metal dichalcogenide (TMD) or a semiconductor material including oxygen.

18. The IC structure of claim 13, wherein:
the second semiconductor material includes a transition metal dichalcogenide (TMD) or a semiconductor material including oxygen.

19. A method of fabricating an integrated circuit (IC) structure, the method comprising:
providing a patterned layer of a first semiconductor material over a substrate, wherein the patterned layer includes:
a first region of the first semiconductor material, a second region of the first semiconductor material, and an opening between the first region and the second region;
providing a second semiconductor material in the opening, wherein one of the first semiconductor material and the second semiconductor material includes an N-type semiconductor material and another of the first semiconductor material and the second semiconductor material includes a P-type semiconductor material; and
forming a first transistor over the first semiconductor material of the first region, a second transistor over the first semiconductor material of the second region, and a third transistor over the second semiconductor material and adjacent to the first and second transistors.

20. The method of claim 19, wherein:
providing the patterned layer of the first semiconductor material includes:
providing a mask with first openings over the substrate,
providing a first semiconductor material in the first openings,
filling the first openings with an insulator material over the first semiconductor material,
recessing the insulator material to expose the first semiconductor material over the mask,
etching the exposed first semiconductor material over the mask, and
removing the mask, wherein removal of the mask forms the opening.
